(19) United States
(12) Patent Application Publication
(10) Pub. No.: US 2025/0203960 A1
(43) Pub. Date: Jun. 19, 2025

(54) ASYMMETRIC EDGE TERMINATION

(71) Applicant: Wolfspeed, Inc., Durham, NC (US)

(72) Inventors: Jae-Hyung Park, Apex, NC (US); Rahul R. Potera, Apex, NC (US); Philipp Steinmann, Durham, NC (US); In-Hwan Ji, Apex, NC (US)

(21) Appl. No.: 18/540,135

(22) Filed: Dec. 14, 2023

(51) Int. Cl. H01L 29/06; H01L 21/04; H01L 29/04; H01L 29/16; H01L 29/872

(52) U.S. Cl. CPC H10D 62/106; H01L 21/0465; H10D 8/60; H10D 62/405; H10D 62/8325

(57) ABSTRACT

A semiconductor device includes a semiconductor epitaxial structure having an off-axis orientation such that a crystallographic direction of the semiconductor epitaxial structure is non-perpendicular to a planar surface of the semiconductor epitaxial structure, and a doped region in the semiconductor epitaxial structure, wherein the doped region is formed by ion implantation into the semiconductor epitaxial structure along the crystallographic direction. The doped region includes a first region and a second region, wherein the first region is perpendicular to the second region. The first region and the second region have equal widths.

### FIELD

The present disclosure relates to semiconductor devices and, more particularly, to semiconductor devices having asymmetric edge termination and to methods of fabricating such devices.

### BACKGROUND

Power semiconductor devices are used to carry large currents and support high voltages. A wide variety of power semiconductor devices are known in the art including, for example, power Metal Oxide Semiconductor Field Effect Transistors (“MOSFET”), Junction Field Effect Transistors (“JFET”), bipolar junction transistors (“BJTs”), Insulated Gate Bipolar Transistors (“IGBT”), Schottky diodes, Junction Barrier Schottky (“JBS”) diodes, merged p-n Schottky (“MPS”) diodes, Gate Turn-Off Thyristors (“GTO”), MOS-controlled thyristors and various other devices. These power semiconductor devices are generally fabricated from monocrystalline silicon semiconductor material, or, more recently, from silicon carbide or gallium nitride based semiconductor materials.

Power semiconductor devices can have a lateral structure or a vertical structure. In a device having a lateral structure, the terminals of the device (e.g., the drain, gate and source terminals for a power MOSFET device) are on the same major surface (i.e., top or bottom) of a semiconductor layer structure. In contrast, in a device having a vertical structure, at least one terminal is provided on each major surface of the semiconductor layer structure (e.g., in a vertical MOSFET device, the source may be on the top surface of the semiconductor layer structure and the drain may be on the bottom surface of the semiconductor layer structure). The semiconductor layer structure may or may not include an underlying substrate. Herein, the term “semiconductor layer structure” refers to a structure that includes one or more semiconductor layers such as semiconductor epitaxial substrates and/or semiconductor epitaxial layers.

A conventional silicon carbide power device typically has a silicon carbide substrate, such as a silicon carbide wafer having a first conductivity type (e.g., an n-type substrate), on which an epitaxial layer structure having the first conductivity type (e.g., n-type) is formed. This epitaxial layer structure (which may include one or more separate layers) functions as a drift region of the power semiconductor device. The active region may be formed on and/or in the drift region. The active region acts as a main junction or region for blocking voltage in the reverse bias direction and providing current flow in the forward bias direction. The device may also have an edge termination region adjacent the active region. One or more power semiconductor devices may be formed on the substrate, and each power semiconductor device will typically have its own edge termination. After the substrate is fully formed and processed, the substrate may be diced to separate the individual edge-terminated power semiconductor devices if multiple devices are formed on the same substrate. The power semiconductor devices may have a unit cell structure in which the active region of each power semiconductor device includes a large number of individual unit cells that are disposed in parallel to each other and that together function as a single power semiconductor device.

Power semiconductor devices are designed to block (in the forward or reverse blocking state) or pass (in the forward operating state) large voltages and/or currents. For example, in the blocking state, a power semiconductor device may be designed to sustain hundreds or thousands of volts of electric potential. However, as the applied voltage approaches or passes the voltage level that the device is designed to block, non-trivial levels of current may begin to flow through the power semiconductor device. Such current, which is typically referred to as “leakage current,” may be highly undesirable. Leakage current may begin to flow if the voltage is increased beyond the design voltage blocking capability of the device, which may be a function of, among other things, the doping and thickness of the drift region. However, current leakage can occur for other reasons, such as failure of the edge termination and/or the primary junction of the device. If the voltage on the device is increased past the breakdown voltage to a critical level, the increasing electric field may result in an uncontrollable and undesirable runaway generation of charge carriers within the semiconductor device, leading to a condition known as avalanche breakdown.

A power semiconductor device may also begin to allow non-trivial amounts of leakage current to flow at a voltage level that is lower than the design breakdown voltage of the device. In particular, leakage current may begin to flow at the edges of the active region, where high electric fields may be experienced due to electric field crowding effects. In order to reduce this electric field crowding (and the resulting increased leakage currents), edge termination structures may be provided that surround part or all of the active region of a power semiconductor device. These edge terminations may spread the electric field out over a greater area, thereby reducing the electric field crowding.

In vertical power semiconductor devices, the blocking voltage rating of the device is typically determined by a number of factors, including the thickness and the doping concentration of the drift region. In particular, to increase the breakdown voltage of the device, the doping concentration of the drift region is decreased and/or the thickness of the drift region is increased. Typically, during the design phase, a desired blocking voltage rating is selected, and then the thickness and doping of the drift region are chosen based on the desired blocking voltage rating. Since the drift region is the current path for the device in the forward “on” state, the decreased doping concentration and increased thickness of the drift region may result in a higher on-state resistance for the device. Thus, there is an inherent tradeoff between the on-state resistance and blocking voltage for these devices.

Superjunction-type drift regions have been introduced in which the drift region is divided into alternating, side-by-side heavily-doped n-type and p-type regions. In vertical semiconductor devices, these side-by-side n-type and p-type regions are often referred to as “pillars.” The pillars may have fin shapes, column shapes or other shapes. The thickness and doping of these pillars may be controlled so that the superjunction will act like a p-n junction with low resistance and a high breakdown voltage. Thus, by using superjunction structures, the conventional tradeoff between the breakdown voltage of the device and the doping level of the drift region may be avoided. Typically, at least some of the pillars are formed via ion implantation, and so-called “deep” implantation is used (e.g., ion implantation depths of 2.5 microns to 5 microns or more) to enhance the effect of the superjunction structure. In superjunction devices, the doping concentration in the drift region may be increased in order to reduce the on-state resistance of the device with reduced effect on the breakdown voltage.

FIG. 1 is a schematic cross-sectional diagram of a conventional power semiconductor device in the form of a JBS diode 10 that has a conventional superjunction-type drift region 30. As shown in FIG. 1, the JBS diode 10 includes a cathode contact 20, an ohmic contact layer 22, an n-type substrate 24, the drift region 30, a p-type blocking junction 40, a channel region 46, a Schottky contact 42 and an anode contact 44. The cathode contact 20 and the anode contact 44 may each comprise a highly conductive metal layer. The Schottky contact 42 may comprise a layer that forms a Schottky junction with the drift region 30 and may comprise, for example, an aluminum layer. The n-type substrate 24 may comprise a silicon carbide substrate that is heavily doped with n-type impurities such as nitrogen or phosphorous. The ohmic contact layer 22 may comprise a metal that forms an ohmic contact to n-type silicon carbide so as to form an ohmic contact to the silicon carbide substrate 24. The p-type blocking junction 40 may be a p-type implanted region in an upper portion of the drift region 30 that is heavily implanted with p-type dopants. The channel region 46 is positioned adjacent the p-type blocking junction 40. The channel region 46 is a semiconductor structure that passes current in the on-state and blocks voltage in the blocking state. Current flows through the channel region 46 when the diode 10 is in its forward on-state.

The drift region 30 may comprise a silicon carbide semiconductor region that includes at least one n-type pillar 32 and at least one p-type pillar 34. The n-type pillar 32 and the p-type pillar 34 may each comprise epitaxially grown silicon carbide regions that are doped with n-type and p-type dopants, respectively. The number of charges in the n-type pillar 32 may be approximately equal to the number of charges in the p-type pillar 34. The n-type and p-type pillars 32, 34 may be formed, for example, by implanting ions into predetermined portions of the drift region 30. As known to those skilled in the art, ions such as n-type or p-type dopants may be implanted in a semiconductor layer or region by ionizing the desired ion species and accelerating the ions at a predetermined kinetic energy as an ion beam towards the surface of a semiconductor layer in an ion implantation target chamber. Based on the predetermined kinetic energy, the desired ion species may penetrate into the semiconductor layer to a certain depth.

Superjunction technology may reduce the specific on-resistance (Rsp) and/or improve power density in high voltage devices. Because the presence of superjunctions reduces the resistance in the drift region of the device, superjunctions are typically more useful for higher voltage devices in which the drift region accounts for a significant portion of the total specific on-resistance of the device.

In a SiC MOSFET device having a blocking voltage of 1200V, the drift region may account for less than 40% of the specific on-resistance, making the use of superjunctions less desirable. However, in a SiC MOSFET device having a blocking voltage of 1700V, the drift region may account for about 60% of the specific on-resistance, making superjunction technology attractive for such devices. However, the drift region of a 1700V MOSFET may be up to 15 microns thick, which may require deep trenching or epitaxial regrowth to form a superjunction structure using currently available technology.

### SUMMARY

A semiconductor device according to some embodiments includes a semiconductor epitaxial structure having an off-axis orientation such that a crystallographic direction of the semiconductor epitaxial structure is non-perpendicular to a planar surface of the semiconductor epitaxial structure, and a doped region in the semiconductor epitaxial structure, wherein the doped region is formed by ion implantation into the semiconductor epitaxial structure along the crystallographic direction. The doped region includes a first region and a second region, wherein the first region is perpendicular to the second region. The first region and the second region have equal widths.

The crystallographic direction may be offset at an angle of less than 10 degrees in a first direction relative to a normal direction that is normal to the planar surface of the semiconductor epitaxial structure.

The crystallographic direction of the semiconductor epitaxial structure may be a crystallographic direction along which implant channeling occurs.

The semiconductor epitaxial structure may have a hexagonal crystal structure, and the crystallographic direction of the semiconductor epitaxial structure may be a <0001> direction of the hexagonal crystal structure.

The doped region may form a guard ring of the semiconductor device.

The semiconductor epitaxial structure may have a first conductivity type and have an epitaxial structure thereon that is configured as a drift region of the semiconductor device. The semiconductor epitaxial structure may have an active region formed on and/or in the drift region that is configured to block voltage in a reverse bias direction and to provide current flow in a forward bias direction, wherein the guard ring is adjacent at least a portion of the active region of the semiconductor epitaxial structure.

The semiconductor epitaxial structure may include silicon carbide.

A method of forming a semiconductor device according to some embodiments includes providing a semiconductor epitaxial structure, providing a mask on the semiconductor epitaxial structure, and forming first and second openings in the mask. The first opening extends in a first direction and has a first width, and the second opening extends in a second direction that is perpendicular to the first direction, and has a second width that is greater than the first width. The method further includes implanting ions into a planar surface of the semiconductor epitaxial structure through the first and second openings in the mask along a direction that is non-perpendicular to the planar surface of the semiconductor epitaxial structure to form a first doped region and a second doped region in the semiconductor substrate corresponding respectively to the first opening and the second opening. The first doped region and the second doped region have equal widths.

A semiconductor device according to some embodiments includes a semiconductor epitaxial structure having an off-axis orientation such that a crystallographic direction of the semiconductor epitaxial structure is non-perpendicular to a planar surface of the semiconductor epitaxial structure, wherein the crystallographic direction is tilted in a first direction toward a planar surface of the semiconductor epitaxial structure, an active region in the semiconductor epitaxial structure, and an edge termination region in the semiconductor epitaxial structure adjacent the active region. The edge termination region comprises a first region and a second region, wherein the first region is parallel to the second region. The first region and the second region may be perpendicular to the first direction, and a width of the edge termination region in the first region in the first direction is smaller than a width of the second region in the edge termination region in the first direction.

The crystallographic direction may be tilted toward the first region and away from the second region.

The edge termination region may be a doped region that is formed by ion implantation into the semiconductor epitaxial structure.

The edge termination region may surround the active region, and may include a third region and a fourth region, wherein the third region is parallel to the fourth region. The third region and the fourth region may be perpendicular to the first region and the second region, and the width of the second region may be equal to widths of the third region and the fourth region.

A method of forming a semiconductor device according to some embodiments includes providing a semiconductor epitaxial structure having an off-axis orientation such that a crystallographic direction of the semiconductor epitaxial structure is non-perpendicular to a planar surface of the semiconductor epitaxial structure, wherein the crystallographic direction is tilted in a first direction toward a planar surface of the semiconductor epitaxial structure, forming an active region in the semiconductor epitaxial structure, and forming an edge termination region in the semiconductor epitaxial structure adjacent the active region. The edge termination region comprises a first region and a second region, wherein the first region is parallel to the second region, and wherein the first region and the second region are perpendicular to the first direction, and a width of the edge termination region in the first region in the first direction is smaller than a width of the edge termination region in the second region in the first direction.

Some embodiments provide a mask pattern for manufacturing a semiconductor device, wherein the mask pattern defines an active region and an edge termination ring adjacent to the active region. The edge termination ring comprises a first region and a second region, wherein the first region is perpendicular to the second region. The first region and the second region have different widths.

The edge termination ring comprises a third region and a fourth region, wherein the third region is parallel to and opposite the first region and the fourth region is parallel to and opposite the second region. The first region and the third region have equal widths and the second region and the fourth region have equal widths.

### BRIEF DESCRIPTION OF THE DRAWINGS

FIG. 1 is a schematic cross-sectional diagram of a conventional power semiconductor device that has a superjunction-type drift region.

FIG. 2 is a schematic diagram illustrating the relative locations of various crystallographic axes in 4H silicon carbide.

FIGS. 3A to 3C illustrate the lattice structure of 4H silicon carbide as viewed along the <0001>, <11-23> and <11-20> crystallographic axes, respectively.

FIG. 4A illustrates the use of ion implantation to form doped regions in an edge termination region according to some embodiments.

FIG. 4B illustrates the use of channeled ion implantation to form doped regions in an edge termination region according to some embodiments.

FIGS. 5A and 5B illustrate the use of channeled ion implantation to form doped regions in an edge termination region with the infinitely thin masks, according to some embodiments.

FIGS. 6A and 6B illustrate the use of channeled ion implantation to form doped regions in an edge termination region with the finitely thin masks, according to some embodiments.

FIG. 7 illustrates another use of channeled ion implantation to form doped regions in an edge termination region of a semiconductor epitaxial structure with masks of equal width and regions with varied widths between the masks, according to some embodiments.

FIG. 8 illustrates a plan view, first sectional side view, and second sectional side view of a semiconductor device with masks of varied widths and regions with varied widths between the masks, according to some embodiments.

FIG. 9 is a cross-section of a portion of a semiconductor device having an off-axis crystal structure showing the path of breakdown current through the device.

FIG. 10 illustrates a semiconductor device with an asymmetric edge termination region according to some embodiments.

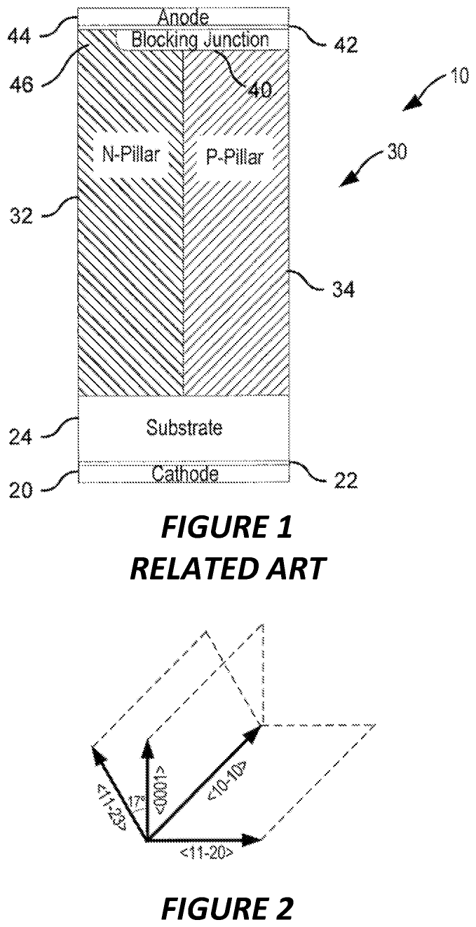

### DETAILED DESCRIPTION OF EMBODIMENTS

Embodiments of the inventive concepts will be described more fully hereinafter with reference to the accompanying drawings. The inventive concepts may, however, be embodied in many different forms and should not be construed as limited to the embodiments set forth herein. Rather, these embodiments are provided so that this disclosure will be thorough and complete, and will fully convey the scope of the inventive concepts to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present inventive concepts. As used herein, the term “and/or” includes any and all combinations of one or more of the associated listed items.

The terminology used herein is for the purpose of describing particular embodiments only and is not intended to be limiting of the inventive concepts. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the inventive concepts belong. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below,” “above,” “upper,” “lower,” “horizontal,” “lateral,” “vertical,” “beneath,” “over,” “on,” etc., may be used herein to describe a relationship of one element, layer or region to another element, layer or region as illustrated in the figures. It will be understood that these terms are intended to encompass different orientations of the device in addition to the orientation depicted in the figures.

Embodiments of the inventive concepts are described herein with reference to cross-section illustrations that are schematic illustrations of idealized embodiments (and intermediate structures) of the inventive concepts. The thickness of layers and regions in the drawings may be exaggerated for clarity. Additionally, variations from the shapes of the illustrations as a result, for example, of manufacturing techniques and/or tolerances, are to be expected. Thus, embodiments of the inventive concepts should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a discrete change from implanted to non-implanted regions. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the inventive concepts.

Some embodiments of the inventive concepts are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

It also will be understood that, as used herein, the terms “row” and “column” indicate two non-parallel directions that may be orthogonal to one another. However, the terms row and column do not indicate a particular horizontal or vertical orientation.

Power semiconductor devices with edge termination regions have conventionally been formed with edge termination spacing that is symmetric along all sides of a die due to uniform implant masks (also referred herein as masks) used during ion implantation. However, when performing channeled implantation, in order to achieve deeper penetration of impurity atoms into the crystal lattice, a semiconductor epitaxial structure is offset at an angle of less than 10 degrees in a first direction relative to a normal direction that is normal to a major surface of the semiconductor epitaxial structure. This offset during channeled implantation may lead to varied widths of doped regions, and varied spacing between doped regions, in the semiconductor epitaxial structure due in part to shadowing from masks on the semiconductor epitaxial structure during channeled implantation.

Channeled implantation can be beneficial in achieving deeper penetration of impurity atoms into the crystal lattice because the stopping power of the particle is much lower in certain crystal directions.

The angle of tilt and the height of the mask modify the critical dimensions of the space between the doped regions and the width of the doped regions such that the drawn features do not translate properly to the physical feature sizes. This can be a problem for the semiconductor device performance. For example, floating field ring (FFR) edge termination is a technique for improving blocking capability, and spacings of these rings are critical for device performance.

Additionally, in 4H-SiC devices, the off-cut epitaxial layer introduces imbalance of depletion charges along the different sides of a device. This leads to an asymmetric leakage current distribution during blocking.

The present disclosure may be directed to, amongst other things, address the spacing issue introduced by devices that utilize FFR and channeled implantation, and also many provide ways to balance the leakage current distributions by modifying the edge termination spacings. This, and other benefits, may be achieved by asymmetric spacings in the edge termination area such that the depletion charges are well balanced.

FIG. 2 is a schematic diagram illustrating the relative locations of various crystallographic axes in 4H silicon carbide. As shown in FIG. 2, the <10-10> crystallographic axis is perpendicular to each of the <0001>, <11-20> and <11-23> crystallographic axes. The <11-20> crystallographic axis is perpendicular to the <0001> crystallographic axis, and the <11-23> crystallographic axis is offset by about 17° from the <0001> crystallographic axis in the direction away from the <11-20> crystallographic axis.

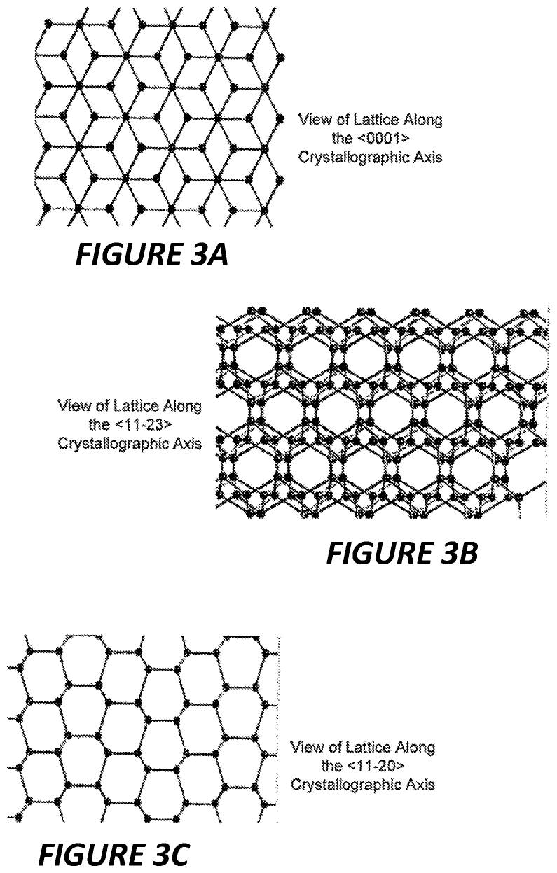

FIGS. 3A to 3C illustrate the lattice structure of 4H silicon carbide as viewed along the <0001>, <11-23> and <11-20> crystallographic axes, respectively.

As shown in FIG. 3A, the density of atoms at the surface (the atoms are shown by the small circles in FIG. 3A) is relatively low, which is a favorable condition for deeper ion implant depths. A plurality of channels are provided between the atoms which allow for channeling of the implanted ions to relatively deeper depths into the semiconductor material. However, the channels themselves are relatively small in cross-sectional area. Relatively speaking, the smaller a channel is in cross-sectional area, the shallower the implant depth. Thus, while ion implantation along the <0001> crystallographic axis will exhibit channeling, the implant depths achievable may be limited.

FIG. 3B illustrates the lattice structure of 4H silicon carbide as viewed along the <11-23> crystallographic axis. The lattice structure will look the same as shown in FIG. 3B when viewed along any of the <−1-123>, <1-213>, <−12-13>, <Feb. 1, 2013> and <−2113> crystallographic axes. Given the hexagonal lattice of 4H silicon carbide, the six crystallographic axes listed above are all offset by 17 degrees from the <0001> crystallographic axis and are spaced apart from each other by 60 degree increments. The vectors that are offset by 17 degrees from the <0001> crystallographic axis form a cone that rotates through 360 degrees. The <11-23>, <−1-123>, <1-213>, <−12-13>, <Feb. 1, 2013> and <−2113> crystallographic axes all extend along this cone, and are separated from each other by 60 degrees. At most rotation angles about this cone, the lattice structure will appear “crowded” with closely-spaced atoms throughout. However, as shown with reference to FIG. 3B, at six different locations that correspond to the <11-23>, <−1-123>, <1-213>, <−12-13>, <Feb. 1, 2013> and <−2113> crystallographic axes, the atoms “line up” so that distinct channels appear in the lattice structure. As can be seen in FIG. 3B, along these six crystallographic axes, the density of atoms at the surface is increased as compared to the example of FIG. 3A, which will typically result in increased scattering of ions. Advantageously, however, the channels that are provided between the atoms have a larger cross-sectional area as compared to the channels in the example of FIG. 3A. This may allow for increased implant depths.

As can be seen in FIG. 3C, when 4H silicon carbide is viewed along the <11-20> crystallographic axis, the density of atoms at the surface may be very low, and channels having large cross-sectional areas are provided within the lattice structure. Such a structure may allow for very deep implant depths. Unfortunately, however, the <11-20> crystallographic axis is typically nearly perpendicular to the major faces of a silicon carbide wafer when the wafer is cut in a traditional manner, and hence it may be difficult to provide silicon carbide wafers that have a major face cut along, or at a relatively small tilt from, the <11-20> crystallographic axis. Thus, ion implantation along the <11-20> crystallographic axis may not be an option in many applications.

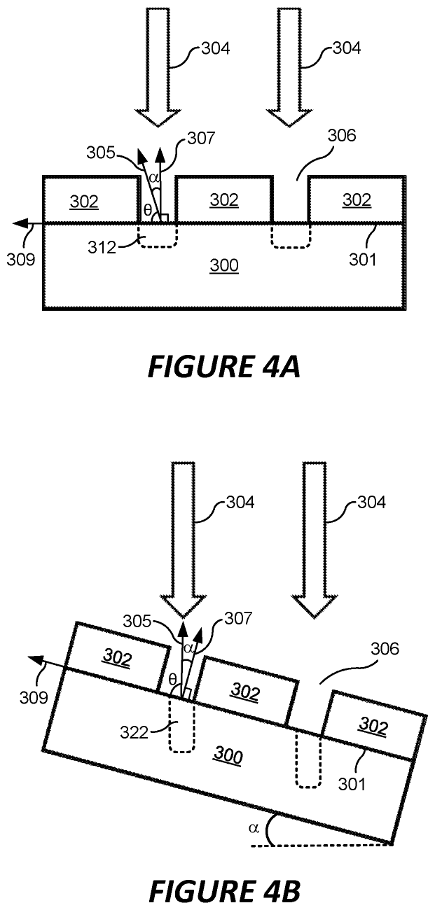

FIG. 4A illustrates the use of ion implantation to form doped regions in an edge termination region according to some embodiments. In this embodiment, the semiconductor epitaxial structure 300 is laid flat while ions 304 are implanted into the semiconductor epitaxial structure through openings 306 in the mask 302 in a normal direction 307 that is normal (i.e., perpendicular) to the upper surface 301 of the substrate 300. In particular, as shown in FIG. 4A, the direction 307 is perpendicular to the upper surface 301 of the substrate 300 and the direction 309 is parallel to the upper surface 301 of the substrate 300. The substrate 300 has an off-axis orientation, wherein the direction 305, which is tilted away from the direction 307 towards the direction 309, is a major crystallographic direction of the crystalline material that forms the substrate 300. For example, the direction 305 may correspond to one of the <0001>, <11-20> or <11-23> crystallographic directions of the crystalline material that forms the substrate 300, and the direction 307 may be tilted from the direction 305 by an angle α of about 1 to 10 degrees. The implanted ions form implanted regions 312 in the substrate 300.

Because the ions 304 are implanted into the substrate 300 at an angle that is not parallel to the major crystallographic direction 305 of the crystalline material that forms the substrate 300 (but rather is tilted by an angle α of about 1 to 10 degrees from the major crystallographic direction), there may be no significant channeling of the implanted ions in the substrate 300.

FIG. 4B illustrates the use of channeled ion implantation to form doped regions in an edge termination region according to some embodiments. As with the substrate 300 shown in FIG. 4A, the semiconductor epitaxial structure 300 in FIG. 4B has an off-axis orientation such that a crystallographic direction of the semiconductor epitaxial structure is offset at an angle of less than about 10 degrees in a first direction relative to a normal direction 307 that is normal to a major surface 301 of the semiconductor epitaxial structure 300. To achieve channeling, the substrate 300 is tilted at a tilt angle α, and the ions 304 are implanted through the openings 306 in the mask 302 and into the semiconductor epitaxial structure 300 in a direction that is parallel to the major crystallographic direction 305 of the crystalline material that forms the substrate 300. As illustrated in FIG. 4B, the ions 304 are implanted in a direction that forms an angle θ with the upper surface 301 of the substrate 300, where α+θ=90 degrees.

The implanted ions 304 form doped regions 322 in the semiconductor epitaxial structure 300 along the major crystallographic direction 305. Because the ions 304 are implanted along the major crystallographic direction 305, the implants may be channeled by the crystal lattice structure of the substrate 300, resulting in much deeper implanted regions 322 for the same implant energy. Thus, the implanted regions 322 shown in FIG. 4B formed via channeled implants may extend deeper into the substrate 300 than the non-channeled implants 312 shown in FIG. 4A.

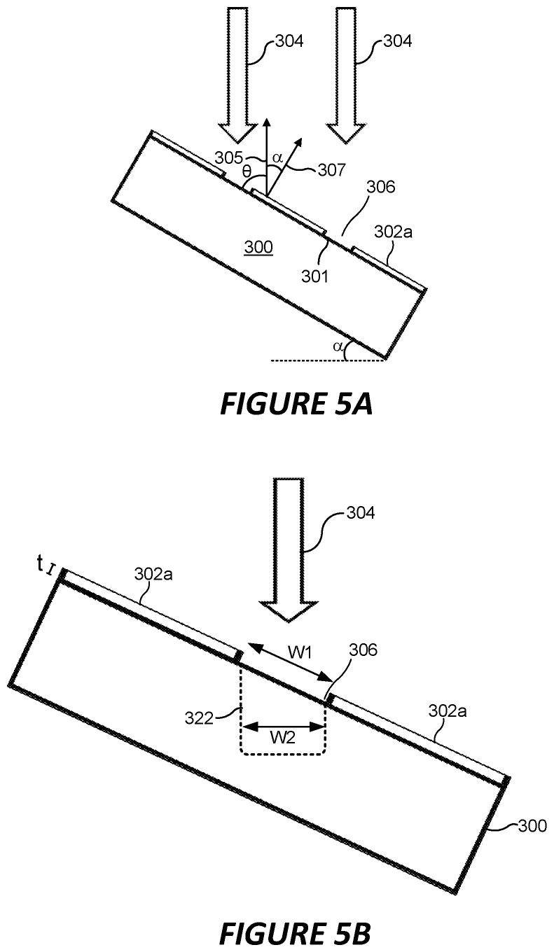

FIGS. 5A and 5B illustrate the use of channeled ion implantation to form doped regions in an edge termination region with an infinitely thin mask 302a, according to some embodiments.

As shown in FIG. 5A, ions 304 are implanted into a semiconductor epitaxial structure 300 through openings 306 in the mask 302a while the substrate 300 is tilted at an angle (α) relative to a direction 307 that is normal to the upper surface 301 of the substrate 300 so that the ions 304 are implanted in a direction that is parallel to a crystallographic direction 305 of the substrate 300 along which channeling occurs. The direction of implantation forms an angle θ with respect to the upper surface 301 of the substrate 300. In this example, the semiconductor epitaxial structure 300 is 4H or 6H silicon carbine and has an off-axis orientation of about 4 degrees, 17 degrees, or another angle in which the direction of ion implantation is aligned with the channeling crystallographic direction.

As shown in FIG. 5B, when the semiconductor epitaxial structure 300 is angled for channeled ion implantation, the width W1 of the openings 306 in the mask 302a in the direction of tilt is different than the width W2 of the implanted region 322 in the substrate 300 in the direction of tilt. This is due to the angle θ at which the semiconductor epitaxial structure 300 is angled relative to the implant angle. The height t of the mask 302a may be relatively negligible when the mask 302a is infinitely thin, such that the width W2 is about equal to (W1*sin (θ)).

Even with an infinitely thin mask 302a, the width W2 is smaller than the width W1 due to the angle of tilt of the semiconductor epitaxial structure 300 relative to the angle of the ion implantation. This difference between the width W1 and W2 may cause problems in the width and/or spacing of doped regions in the semiconductor epitaxial structure 300. This issue is amplified because the angle of the semiconductor epitaxial structure 300 may affect the ion implantation of certain doped regions of the semiconductor epitaxial structure 300 (e.g., a second region of the doped region that has a width in a direction of tilt) more than other doped regions of the semiconductor epitaxial structure (e.g., a first region of the doped region that has a width in a direction perpendicular the direction of tilt). This is discussed in more detail below.

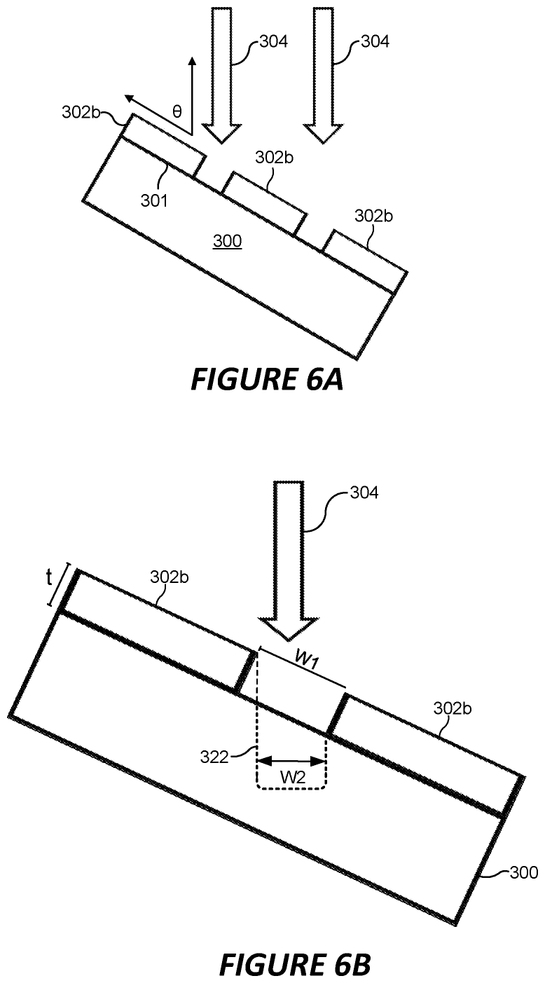

FIGS. 6A and 6B illustrate the use of channeled ion implantation to form doped regions in an edge termination region with the finitely thin masks 302b, according to some embodiments.

As shown in FIG. 6B, when the mask 302b has a finite thickness t, the width W2 of the implanted region in the direction of tilt is affected by the shadowing of the mask 302b due to the height t of the mask 302b and the angle the semiconductor epitaxial structure 300 is titled during the channeled ion implantation. In this example, the width W2 is equal to [W1−t*Cos(θ)]*Sin(θ). As can be seen, the width W2 is decreased by t*Cos(θ)*Sin(θ).

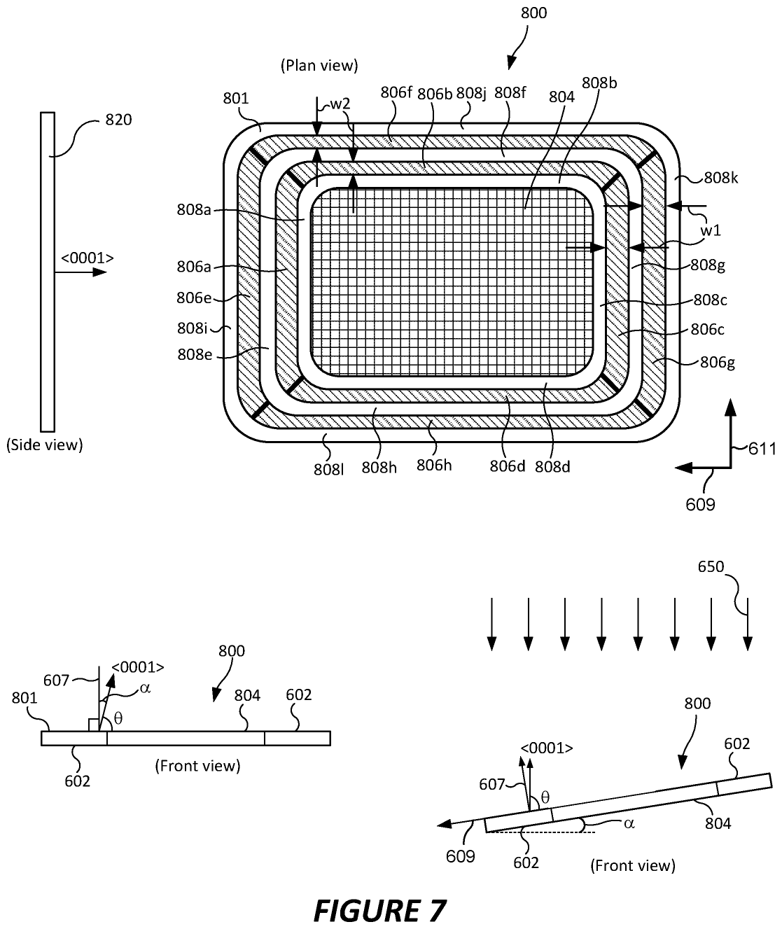

FIG. 7 illustrates another use of channeled ion implantation to form doped regions in an edge termination region 602 of a semiconductor structure 800 with a mask 808 including mask portions 808a-l of equal width that define openings 806a-h having varied widths between the mask portions 808a-l, according to some embodiments. In particular, FIG. 7 shows a side, plan, and front view of the semiconductor structure 800 that includes a semiconductor epitaxial structure 820. The semiconductor epitaxial structure 820 includes a planar upper, or major, surface 801. A direction 607 is normal to the upper surface 801 of the semiconductor epitaxial structure 820. First and second directions 609, 611, which are parallel to the plane of the upper surface 801 of the semiconductor epitaxial structure 820, are mutually perpendicular and are both perpendicular to the normal direction 607.

The semiconductor epitaxial structure 820 has a crystalline structure that is cut at an off-axis angle α relative to the <0001> crystallographic direction toward the first direction 609, so that the <0001> crystallographic direction is tilted away from the normal direction 607. In some embodiments, the off-axis angle may be tilted toward a crystallographic direction that is perpendicular to the <0001> crystallographic direction, such as the <11-20> or <10-10> crystallographic directions. The off-axis angle α may be about 3° to 5°, and in some embodiments about 0° to 10°. In the example shown in FIG. 7, the semiconductor epitaxial structure 820 is cut at an off-axis angle α relative to the <0001> crystallographic direction that is tilted toward the first direction 609.

As shown in plan view of FIG. 7, a mask 808 including a plurality of mask portions 808a-l are formed on the surface of the semiconductor epitaxial structure 820. In some embodiments, some of the mask portions 808a-l may be connected such that they form a single mask portion. For example, mask portions 808a-d may form a first mask portion and mask portions 808e-h may form a second mask portion.

In some embodiments, the mask 808 obstructs the implanted ions 650 from entering the semiconductor epitaxial structure 820 during the ion implantation process.

Mask portions 808a-d are adjacent an active region 804 of the semiconductor epitaxial structure 820 and are adjacent openings 806a-d. Mask portions 808e-h define openings 806a-d and openings 806e-h. The openings 806a-h expose the semiconductor epitaxial structure 820 to the ions for ion implantation. The exposed regions 806a, 806c, 806e, 806g generally extend in the second direction 611 and have a first width w1 in the first direction (i.e., in the direction of tilt of the semiconductor epitaxial structure 820). The exposed regions 806b, 806d, 806f, 806h generally extend in the first direction 609 (i.e., in the direction of tilt of the semiconductor epitaxial structure 820) and have a second width w2 in the second direction. The first width w1 may be greater than the second width w2 to account for the narrowing of the implanted region in the direction of tilt when the substrate 320 is tilted for ion implantation, so that when the implantation is performed, the implanted regions of the substrate 320 beneath the exposed regions 806a, 806c, 806e, 806g that are perpendicular to the direction of tilt will have the same width as the implanted regions of the substrate 320 beneath the exposed regions 806b, 806d, 806f, 806h that are parallel to the direction of tilt.

In some embodiments, the mask portions 808a may have a first width in a direction parallel to the first direction 609. The mask portion 808b may have a second width, that is equal to the first width, in the second direction 611. In some embodiments, each of mask portions 808a-l have the same width. However, the spacing between the mask portions 808a-l may vary in order to achieve doped regions within the regions 806a-h that are equal in width.

As shown in FIG. 7, the exposed regions 806a, 806c, 806e, and 806g have a larger width than the exposed regions 806b, 806d, 806f, and 806g. These varied width regions may provide one or more doped regions in the semiconductor epitaxial structure 320 that have equal widths in the semiconductor epitaxial structure 320 are equal when ions 650 are implanted into the semiconductor epitaxial structure 820 through the mask openings. This may be possible, because when the semiconductor epitaxial structure is offset at an angle in a first direction relative to a normal direction 603 that is normal to a major surface of the semiconductor epitaxial structure, shadowing occurs more by the mask portions 808a, 808c, 808e, 808g, 808i, and 808k and not as much by the mask portions 808b, 808d, 808f, 808h, 808j, and 808l. This is because the mask portions 808a, 808c, 808e, 808g, 808i, and 808k are perpendicular to the tilt direction while the mask portions 808b, 808d, 808f, 808h, 808j, and 808l are parallel to the tilt direction.

Due to the varied widths of the exposed regions 806a-h between the masks, the width of the doped regions may be equal. The doped region may include a first region and a second region. In the example of FIG. 7, the regions 806a, 806d, 806e, and 806h are included in the second region that has a width in a direction perpendicular to the first direction, and the regions 806b, 806c, 806f, and 806g are included in the first regions that have a width in a direction parallel to the first direction. The width of the doped regions within the first region may be equal to the width of the doped regions within the second region.

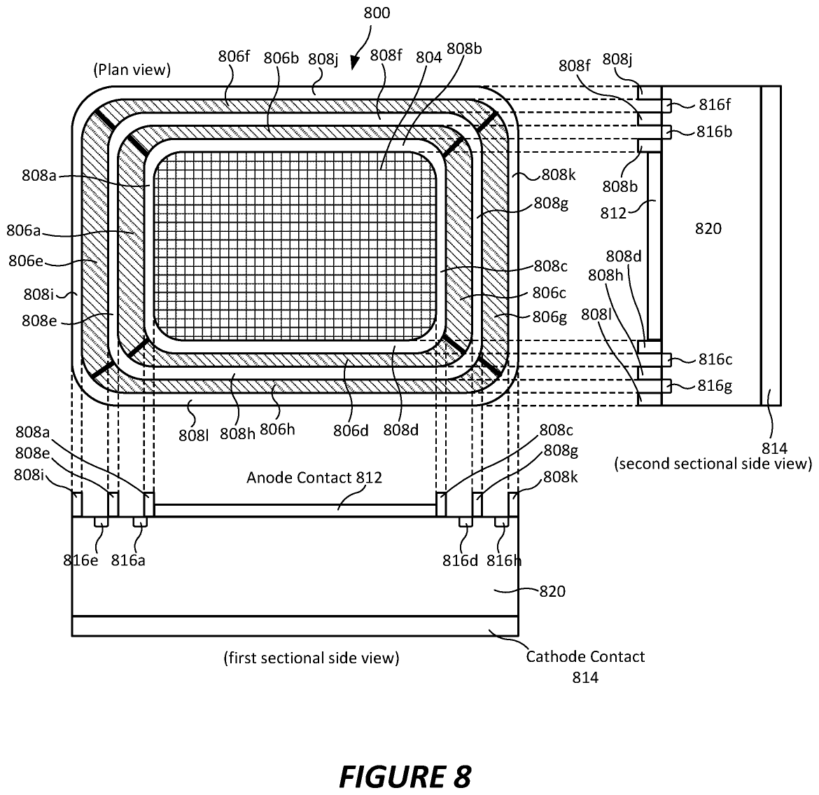

FIG. 8 illustrates a plan view, first sectional side view, and second sectional side view of a semiconductor device 800 with mask portions 808a-l of varied widths and regions 806a-h with varied widths between the mask portions 808a-l, according to some embodiments. By varying the width of both the mask portions 808a-l and the regions 806a-h between the mask portions 808a-l, the spacing width between the doped regions 816a-h may be equal in the termination region and the width of the doped regions 816a-h may be equal in the termination region. This may improve the performance of the semiconductor device, for example, by improving the dissipation of voltage in the edge termination regions.

The semiconductor device 800 may include a semiconductor epitaxial structure 820 having an off-axis orientation such that a crystallographic direction of the semiconductor epitaxial structure is offset at an angle of less than 10 degrees in a first direction relative to a normal direction that is normal to a major surface of the semiconductor epitaxial structure 820. Additionally, the semiconductor device 800 may include a doped region (e.g., one or more of doped regions 816a-h) in the semiconductor epitaxial structure 820, wherein the doped region is formed by ion implantation into the semiconductor epitaxial structure 820 along the crystallographic direction. The doped region may include a first region (e.g., one or more of doped regions 816b, 816c, 816f, and 816g) and a second region (e.g., one or more of doped regions 816a, 816d, 816e, and 816h). The first region has a width in a direction parallel to the first direction and the second region has a width in a direction perpendicular to the first direction, wherein the width of the first region is equal to the width of the second region. For example, the width of the doped regions 816b, 816c, 816f, and 816g which have widths that are parallel the first direction are equal to the width of the doped regions 816a, 816d, 816e, and 816h which have widths that are perpendicular to the first direction.

The doped regions 816a-h are formed in the semiconductor epitaxial structure 820 through channeled ion implantation. In some embodiments, the ions include electrically active ions. In additional or alternative embodiments, the ions include p-type dopant atoms such as aluminum or boron ions.

In some embodiments, the ions are implanted with an implant energy of 10 keV or greater.

In some embodiments, the semiconductor device 800 includes an anode contact 812 formed on the top surface of the semiconductor epitaxial structure 820 and a cathode contract 814 formed on the bottom surface of the semiconductor epitaxial structure 820.

In some embodiments, the crystallographic direction of the semiconductor epitaxial structure 820 is a crystallographic direction along which implant channeling occurs.

In some embodiments, the semiconductor epitaxial structure 820 includes a hexagonal crystal structure, and the crystallographic direction of the semiconductor epitaxial structure includes a <0001> direction of the hexagonal crystal structure.

In some embodiments, the doped region (e.g., doped regions 816 a-h) includes a guard ring. In these and other embodiments, the semiconductor epitaxial structure 820 includes a first conductivity type and having an epitaxial structure thereon that is configured as a drift region of the semiconductor device 800. The semiconductor epitaxial structure 820 has an active region formed on and/or in the drift region that is configured to block voltage in a reverse bias direction and providing current flow in a forward bias direction, wherein the guard ring is adjacent at least a portion of the active region of the semiconductor epitaxial structure 820.

In some embodiments, the semiconductor epitaxial structure includes silicon carbide. Additionally or alternatively, the semiconductor epitaxial structure includes a n-type conductivity. In some embodiments, the doped region includes a p-type conductivity.

The semiconductor device 800 may be formed by providing a semiconductor epitaxial structure 820 having an off-axis orientation such that a crystallographic direction of the semiconductor epitaxial structure 820 is offset at an angle of less than 10 degrees in a first direction relative to a normal direction that is normal to a major surface of the semiconductor epitaxial structure. Additionally, the semiconductor device 800 is formed by providing a mask (e.g., mask portions 808a-l) adjacent a doped region (e.g., regions 806a-h) in the semiconductor epitaxial structure 820 that is a first width in a direction parallel to the first direction and a second width in a direction perpendicular to the first direction.

The semiconductor device 800 is further formed by implanting ions into the semiconductor epitaxial structure 820 along the crystallographic direction. The doped region includes a first region and a second region. The first region has a width in the direction parallel to the first direction and the second region has a width in the direction perpendicular to the first direction, and the width of the first region is equal to the width of the second region.

In some embodiments, the crystallographic direction of the semiconductor epitaxial structure 820 is a crystallographic direction along which implant channeling occurs.

In some embodiments, the semiconductor epitaxial structure 820 includes a hexagonal crystal structure, and the crystallographic direction of the semiconductor epitaxial structure 820 includes a <0001> direction of the hexagonal crystal structure.

In some embodiments, the implanting of ions into the doped region (e.g., doped regions 816a-d) forms a guard ring. In some of these embodiments, the guard ring includes a p-type conductivity. Additionally or alternatively, the semiconductor epitaxial structure 820 includes a first conductivity type and having an epitaxial structure thereon that is configured as a drift region of the semiconductor device 800. The semiconductor epitaxial structure 820 may have an active region formed on and/or in the drift region that is configured to block voltage in a reverse bias direction and providing current flow in a forward bias direction. The guard ring may be adjacent at least a portion of the active region of the semiconductor epitaxial structure 820.

In some embodiments, the semiconductor epitaxial structure 820 includes silicon carbide.

In some embodiments, the semiconductor epitaxial structure 820 comprises a n-type conductivity.

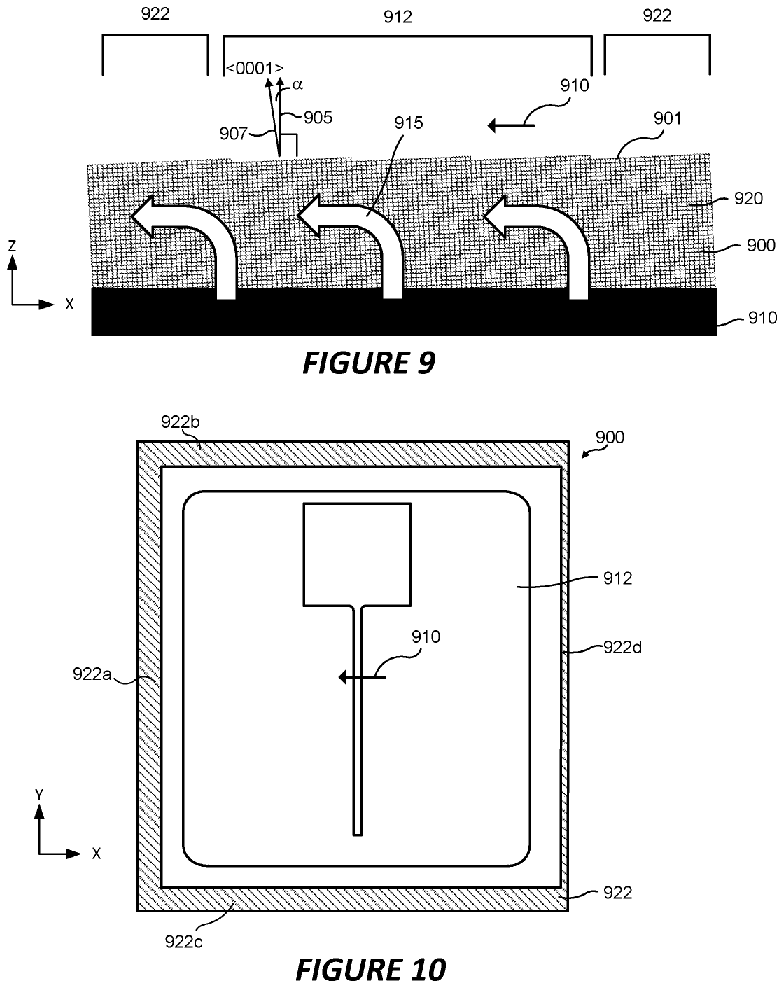

FIG. 9 is a cross-section of a portion of a semiconductor device 900 having a 4-degree off-axis crystal structure showing the path of breakdown current through the device. In particular, the device 900 includes a semiconductor epitaxial structure 920 having a 4-degree off-axis orientation. A drain contact 910 is formed on a bottom surface of the semiconductor epitaxial structure 920. The top surface 901 of the semiconductor epitaxial structure 920 is planar and generally parallel to the x-axis shown in FIG. 9. A normal direction 905 is normal to the top surface 901 of the semiconductor epitaxial structure 920. The semiconductor epitaxial structure 920 is cut at an off-axis angle such that a major crystallographic direction 907, such as the <0001> direction, of the semiconductor epitaxial structure 920 is tilted at an off axis angle α of about 4 degrees towards the positive x-direction.

The semiconductor device 900 has an active region 912 surrounded by an edge termination region 922. Other features and elements of the semiconductor device 900 are omitted for clarity.

It is observed that due to the off-axis crystal orientation, avalanche breakdown current 915 in the device from the drain 910 into the semiconductor epitaxial structure 920 flows generally upward and sideways toward the side of the semiconductor epitaxial structure 920 in a direction 910 opposite to the direction in which the crystallographic direction 907 is tilted relative to the normal direction 905. That is, in the semiconductor device 900 shown in FIG. 9, the breakdown current 915 flows upward and in the negative x-direction 910 when the major crystallographic direction 907 of the semiconductor epitaxial structure 920 is tilted at an off axis angle α towards the positive x-direction.

When the device 900 has a uniform or near uniform width edge termination region 922 on both sides of the active region 912, e.g., a leftward flow of avalanche current may cause breakdown of the edge termination primarily on the left side of the device 900. Such uneven breakdown characteristics may reduce the overall breakdown voltage of the device 900.

According to some embodiments, to improve the performance of the semiconductor device 900, it may be beneficial to compensate for this avalanche current flow, e.g. to the left, by varying the width of the edge termination region, such as by decreasing the width of the edge termination region on the opposite side of the device 900.

FIG. 10 illustrates a semiconductor device structure 900 according to some embodiments having an asymmetric edge termination region 922 that surrounds an active region 912. As shown in FIG. 10, the edge termination region 922d on the side of the device structure 900 opposite to the side toward which avalanche current preferentially flows is narrower than the edge termination regions 922a-c on the other sides of the device 900. This may cause the device 900 to exhibit more balanced avalanche breakdown characteristics.

Accordingly, referring to FIGS. 9 and 10, a semiconductor device 902 according to some embodiments includes a semiconductor epitaxial structure 920 having an off-axis orientation such that a crystallographic direction 907 of the semiconductor epitaxial structure 920 is non-perpendicular to a planar surface 901 of the semiconductor epitaxial structure 920. The crystallographic direction 907 is tilted in a first direction (e.g., the x-direction) toward a planar surface 901 of the semiconductor epitaxial structure 920. The semiconductor device includes an active region 912 in the semiconductor epitaxial structure 920 and an edge termination region 922 in the semiconductor epitaxial structure 920 adjacent the active region 912.

The edge termination region 922 includes a first region 922d and a second region 922a that is parallel to the first region 922d. The first region 922d and the second region 922a are perpendicular to the first direction. A width of the first region 922d in the first direction is smaller than a width of the second region 922a in the first direction.

The crystallographic direction 907 may be tilted in toward the first region 922d and away from the second region 922a.

The edge termination region 922 may be a doped region that is formed by ion implantation into the semiconductor epitaxial structure 920.

As shown in FIG. 10, the edge termination region 922 may surround the active region 912, and the edge termination region 922 may include a third region 922b and a fourth region 922c, wherein the third region 922b is parallel to the fourth region 922c, and wherein the third region 922b and the fourth region 922c are perpendicular to the first region 922d and the second region 922a. The width of the second region 922d may be equal to widths of the third region 922b and the fourth region 922c.

A method of forming a semiconductor device includes providing a semiconductor epitaxial structure 920 having an off-axis orientation such that a crystallographic direction 907 of the semiconductor epitaxial structure 920 is non-perpendicular to a planar surface 901 of the semiconductor epitaxial structure 920. The crystallographic direction 907 is tilted in a first direction (e.g., the x-direction) toward a planar surface 901 of the semiconductor epitaxial structure 920.

The method further includes forming an active region 912 in the semiconductor epitaxial structure 920 and an edge termination region 922 in the semiconductor epitaxial structure 920 adjacent the active region 912.

The edge termination region 922 includes a first region 922d and a second region 922a that is parallel to the first region 922d. The first region 922d and the second region 922a are perpendicular to the first direction. A width of the first region 922d in the first direction is smaller than a width of the second region 922a in the first direction.

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

In the drawings and specification, there have been disclosed typical embodiments of the invention and, although specific terms are employed, they are used in a generic and descriptive sense only and not for purposes of limitation, the scope of the invention being set forth in the following claims.

1. A semiconductor device, comprising:
a semiconductor epitaxial structure having an off-axis orientation such that a crystallographic direction of the semiconductor epitaxial structure is non-perpendicular to a planar surface of the semiconductor epitaxial structure; and
a doped region in the semiconductor epitaxial structure, wherein the doped region is formed by ion implantation into the semiconductor epitaxial structure along the crystallographic direction;
wherein the doped region comprises a first region and a second region, wherein the first region is perpendicular to the second region; and
wherein the first region and the second region have equal widths.

2. The semiconductor device of claim 1, wherein the crystallographic direction is offset at an angle of less than 10 degrees relative to a normal direction that is normal to the planar surface of the semiconductor epitaxial structure.

3. The semiconductor device of claim 1, wherein the crystallographic direction of the semiconductor epitaxial structure is a crystallographic direction along which implant channeling occurs.

4. The semiconductor device of claim 1, wherein the semiconductor epitaxial structure comprises a hexagonal crystal structure, and wherein the crystallographic direction of the semiconductor epitaxial structure comprises a <0001> direction of the hexagonal crystal structure.

5. The semiconductor device of claim 1, wherein the doped region comprises a guard ring.

6. The semiconductor device of claim 5, wherein the semiconductor epitaxial structure comprises a first conductivity type and having an epitaxial structure thereon that is configured as a drift region of the semiconductor device, wherein the semiconductor epitaxial structure has an active region formed on and/or in the drift region that is configured to block voltage in a reverse bias direction and providing current flow in a forward bias direction, wherein the guard ring is adjacent at least a portion of the active region of the semiconductor epitaxial structure.

7. The semiconductor device of claim 1, wherein the semiconductor epitaxial structure comprises silicon carbide.

8. A method of forming a semiconductor device, comprising:
providing a semiconductor epitaxial structure;
providing a mask on the semiconductor epitaxial structure;
forming first and second openings in the mask, wherein the first opening extends in a first direction and has a first width, and the second opening extends in a second direction that is perpendicular to the first direction, and has a second width that is greater than the first width; and
implanting ions into a planar surface of the semiconductor epitaxial structure through the first and second openings in the mask along a direction that is non-perpendicular to the planar surface of the semiconductor epitaxial structure to form a first doped region and a second doped region in the semiconductor substrate corresponding respectively to the first opening and the second opening;
wherein the first doped region and the second doped region have equal widths.

9. The method of claim 8, wherein the semiconductor epitaxial structure has an off-axis orientation such that a crystallographic direction of the semiconductor epitaxial structure is non-perpendicular to the planar surface of the semiconductor epitaxial structure, wherein implanting the ions is performed along the crystallographic direction.

10. The method of claim 9, wherein the crystallographic direction of the semiconductor epitaxial structure is a crystallographic direction along which implant channeling occurs.

11. The method of claim 9, wherein the semiconductor epitaxial structure comprises a hexagonal crystal structure, and wherein the crystallographic direction of the semiconductor epitaxial structure comprises a <0001> direction of the hexagonal crystal structure.

12. The method of claim 9, wherein the first doped region and the second doped region form part of a guard ring.

13. The method of claim 8, wherein the semiconductor epitaxial structure comprises silicon carbide.

14. A semiconductor device, comprising:
a semiconductor epitaxial structure having an off-axis orientation such that a crystallographic direction of the semiconductor epitaxial structure is non-perpendicular to a planar surface of the semiconductor epitaxial structure,
an active region in the semiconductor epitaxial structure; and
an edge termination region in the semiconductor epitaxial structure adjacent the active region;
wherein the edge termination region comprises a first region and a second region, wherein the first region is parallel to the second region; and
wherein a width of the edge termination region in the first region is smaller than a width of the edge termination region in the second region.

15. The semiconductor device of claim 14, wherein the crystallographic direction is tilted in a first direction toward a planar surface of the semiconductor epitaxial structure;
wherein the first region and the second region extend in a second direction that is perpendicular to the first direction.

16. The semiconductor device of claim 15, wherein the width of the first region is the width of the first region in the first direction and the width of the second region is the width of the second region in the first direction.

17. The semiconductor device of claim 14, wherein the edge termination region comprises a plurality of guard rings.

18. The semiconductor device of claim 14, wherein the first region and the second region are on opposite sides of the active region.

19. The semiconductor device of claim 14, wherein the crystallographic direction is tilted toward the second region and away from the first region.

20. The semiconductor device of claim 14, wherein the edge termination region comprises a doped region that is formed by ion implantation into the semiconductor epitaxial structure.

21. The semiconductor device of claim 14, wherein the edge termination region surrounds the active region, wherein the edge termination region comprises a third region and a fourth region, wherein the third region is parallel to the fourth region, and wherein the third region and the fourth region are perpendicular to the first region and the second region; and
wherein the width of the second region is equal to widths of the third region and the fourth region.

22. A method of forming a semiconductor device, comprising:
providing a semiconductor epitaxial structure having an off-axis orientation such that a crystallographic direction of the semiconductor epitaxial structure is non-perpendicular to a planar surface of the semiconductor epitaxial structure;
forming an active region in the semiconductor epitaxial structure; and
forming an edge termination region in the semiconductor epitaxial structure adjacent the active region;
wherein the edge termination region comprises a first region and a second region, wherein the first region is parallel to the second region; and
wherein a width of the edge termination region in the first region is smaller than a width of the edge termination region in the second region.

23. The method of claim 22, wherein the crystallographic direction is tilted in a first direction toward a planar surface of the semiconductor epitaxial structure;
wherein the first region and the second region extend in a second direction that is perpendicular to the first direction.

24. The method of claim 23, wherein the width of the first region is the width of the first region in the first direction and the width of the second region is the width of the second region in the first direction.

25. The method of claim 22, wherein the edge termination region comprises a plurality of guard rings.

26. The method of claim 22, wherein the first region and the second region are on opposite sides of the active region.

27. The method of claim 22, wherein the crystallographic direction is tilted toward the second region and away from the first region.

28. The method of claim 22, wherein the edge termination region comprises a doped region that is formed by ion implantation into the semiconductor epitaxial structure.

29. The method of claim 22, wherein the edge termination region surrounds the active region, wherein the edge termination region comprises a third region and a fourth region, wherein the third region is parallel to the fourth region, and wherein the third region and the fourth region are perpendicular to the first region and the second region; and
wherein the width of the second region is equal to widths of the third region and the fourth region.

30. A mask pattern for manufacturing a semiconductor device, wherein the mask pattern defines an active region and an edge termination ring adjacent to the active region;
wherein the edge termination ring comprises a first region and a second region, wherein the first region is perpendicular to the second region; and
wherein the first region and the second region have different widths.

31. The mask pattern of claim 30, wherein the edge termination ring comprises a third region and a fourth region, wherein the third region is parallel to the first region and the fourth region is parallel to the second region, and wherein the first region and the third region have equal widths and the second region and the fourth region have equal widths.
